(19) United States
(12) Patent Application Publication
(10) Pub. No.: US 2026/0087226 A1
(43) Pub. Date: Mar. 26, 2026

(54) BLOCKAGE AWARE FLUE ROUTING IN BUFFER BAYS

(71) Applicant: International Business Machines Corporation, Armonk, NY (US)

(72) Inventors: Joseph Koone, Poughkeepsie, NY (US); Christian Roth, Holzgerlingen (DE); Edward Hughes, Archbald, PA (US); Adam P. Matheny, Hyde Park, NY (US); Smitha Reddy, Fishkill, NY (US); Ronald Dennis Rose, Essex Junction, VT (US); Robert John Allen, Jericho, VT (US); Mitchell R. DeHond, Essex Junction, VT (US); Yuehua Huang, Doylestown, PA (US); Gustavo Enrique Tellez, Hyde Park, NY (US)

(21) Appl. No.: 18/892,612

(22) Filed: Sep. 23, 2024

(51) Int. Cl. G06F 30/394; G06F 30/31; G06F 30/392

(52) U.S. Cl. CPC G06F 30/394; G06F 30/31; G06F 30/392

(57) ABSTRACT

Embodiments of the invention are directed to a computer-implemented method of performing routing operations for an integrated circuit (IC) design. The computer-implemented method includes identifying, using a processor system, a location of a buffer bay in the IC design. One or more blockage areas associated with the buffer bay are identified. A pattern of the one or more blockage areas is determined, and the pattern includes one or more blockage area exit locations. A component is placed within the buffer bay. Based at least in part on information of the pattern, a routing path is determined from the component through the pattern to one of the one or more blockage area exit locations.

### BACKGROUND

The present invention relates in general to computer tools that assist with the design of integrated circuits. More specifically, the present invention relates to computing systems, computer-implemented methods, and computer program products that implement integrated circuit (IC) design techniques that perform “blockage aware” interconnect flue routing in buffer bay regions an IC design, including complex and dense IC designs such as very large scale integration (VLSI) ICs.

“Electronic design automation” (EDA) refers to hardware and/or software tools that assist with a variety of electronic system design operations, including, for example, so-called “place and route” operations that map out the placement of electronic components/circuitry, along with the routing of interconnect structures needed to connect the placed components/circuitry. “Flue routing” is a single specialized routing function for routing pin (if no via mesh is present) and via mesh connections within buffer bays. A via mesh is a type of interconnect configured to provide multiple conductive pathways from one or more points in one IC layer to one or more points in another IC layer of the same IC.

Buffers are included in IC designs to achieve timing and signal integrity requirements. In general, a buffer is a circuit that amplifies signal current but leaves the signal's voltage unchanged, thereby boosting the current capacity of a weak signal source so the signal can drive a load. Buffer bays are a hierarchical structure in IC designs where child design buffer-related resources are shared with the parent design. To communicate the shared child/parent resource, blockages or blockage areas, are used within the buffer bay where placement of other cells or components is restricted or prohibited. These buffer bays have different resource allocation depending upon their orientation known as horizontal or vertical buffer bays. Additionally, the “top” of the buffer bay will change depending upon the maximum routing layer (ceiling) of the child design. In IC design, the “top” of the buffer bay typically refers to the highest-level or most critical area within the buffer or staging region of the IC design layout.

### SUMMARY

Embodiments of the invention are directed to a computer-implemented method of performing routing operations for an integrated circuit (IC) design. The computer-implemented method includes identifying, using a processor system, a location of a buffer bay in the IC design. One or more blockage areas associated with the buffer bay are identified. A pattern of the one or more blockage areas is determined, and the pattern includes one or more blockage area exit locations. A component is placed within the buffer bay. Based at least in part on information of the pattern, a routing path is determined from the component through the pattern to one of the one or more blockage area exit locations.

Embodiments of the invention are also directed to computer systems and computer program products having substantially the same features, technical effects, and technical benefits as the computer-implemented method described above.

Additional features and advantages are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1 depicts an exemplary computing environment operable to implement aspects of the invention;

FIG. 2 depicts a simplified block diagram illustrating an electronic design automation (EDA) system operable to implement aspects of the invention;

FIG. 3 depicts a simplified block diagram of an IC (e.g., a VLSI IC) having buffer bay regions that can be designed and routed using embodiments of the invention;

FIG. 4A depicts a simplified block diagram illustrating top-down views of an IC (e.g., a VLSI IC) having buffer bays that can be designed and routed using embodiments of the invention;

FIG. 4B depicts zoomed-in side-views of example instances of the horizontal buffy bays and vertical buffer bays shown in FIG. 4A;

FIG. 5A depicts a simplified block diagram illustrating a top-down view of a buffer bay and surrounding blockage areas in accordance with embodiments of the invention;

FIG. 5B depicts a simplified block diagram illustrating a side-view of the buffer bay and surrounding blockage areas shown in FIG. 5A taken along the imaginary buffer bay slice shown in FIG. 5A;

FIG. 6A depicts a simplified block diagram of a via mesh interconnect configuration that can be routed to a buffer bay in a blockage-aware manner using embodiments of the invention;

FIG. 6B depicts a simplified block diagram of a via mesh specification generated in accordance with embodiments of the invention;

FIG. 7 depicts a flow diagram illustrating a computer-implemented method in accordance with embodiments of the invention;

FIG. 8 depicts a net generated in accordance with embodiments of the invention;

FIG. 9 depicts a flow diagram illustrating a computer-implemented method in accordance with embodiments of the invention;

FIG. 10 depicts a flow diagram illustrating a computer-implemented method in accordance with embodiments of the invention;

FIG. 11 depicts a flow diagram illustrating a computer-implemented method in accordance with embodiments of the invention;

FIG. 12 depicts a flow diagram illustrating a computer-implemented method in accordance with embodiments of the invention;

FIG. 13 depicts a flow diagram illustrating a computer-implemented method in accordance with embodiments of the invention;

FIG. 14 depicts a flow diagram illustrating a computer-implemented method in accordance with embodiments of the invention;

FIG. 15 depicts a flow diagram illustrating a computer-implemented method in accordance with embodiments of the invention;

FIG. 16 depicts a simplified block diagram illustrating a routing connection between of a via mesh specification of one cell and a via mesh specification (including a flue region) of another cell in accordance with embodiments of the invention;

FIG. 17 depicts a non-limiting example of a via mesh specification adjustment in accordance with embodiments of the invention;

FIG. 18A illustrates a non-limiting example of a cell that has a non-buffer bay mesh routed;

FIG. 18B depicts a cell in a buffer bay mesh specification that is unrouteable due to blockage, along with a buffer bay mesh specification that has been adjusted to be routable with similar resistance/capacitance (RC) characteristics;

FIG. 19 depicts a simplified block diagram of vertical buffer bays and associated blockage patterns to which embodiments of the invention can be applied; and

FIG. 20A depicts a simplified block diagram of horizontal buffer bays and associated blockage patterns to which embodiments of the invention can be applied; and

FIG. 20B depicts a simplified block diagram of horizontal buffer bays and associated blockage patterns to which embodiments of the invention can be applied.

In the accompanying figures and following detailed description of the disclosed embodiments, the various elements illustrated in the figures are provided with three digit reference numbers. In some instances, the leftmost digits of each reference number corresponds to the figure in which its element is first illustrated.

### DETAILED DESCRIPTION

For the sake of brevity, conventional techniques related to making and using aspects of the invention may or may not be described in detail herein. In particular, various aspects of computing systems and specific computer programs to implement the various technical features described herein are well known. Additionally, conventional techniques related to semiconductor device and IC design and fabrication may or may not be described in detail herein. Moreover, the various tasks and process steps described herein can be incorporated into a more comprehensive procedure or process having additional steps or functionality not described in detail herein. Thus, in the interest of brevity, many conventional implementation details are only mentioned briefly herein or are omitted entirely without providing the well-known system and/or process details.

Many of the functional units (or functionalities) of the systems described in this specification have been labeled as modules. Embodiments of the invention apply to a wide variety of module implementations. For example, a module can be implemented as a hardware circuit including custom VLSI circuits or gate arrays, off-the-shelf semiconductors such as logic chips, transistors, or other discrete components. A module can also be implemented in programmable hardware devices such as field programmable gate arrays, programmable array logic, programmable logic devices or the like. Modules can also be implemented in software for execution by various types of processors. An identified module of executable code can, for instance, include one or more physical or logical blocks of computer instructions which can, for instance, be organized as an object, procedure, or function. Nevertheless, the executables of an identified module need not be physically located together but can include disparate instructions stored in different locations which, when joined logically together, function as the module and achieve the stated purpose for the module.

The components/modules of the systems illustrated herein are depicted separately for ease of illustration and explanation. In embodiments of the invention, the functions performed by the components/modules can be distributed differently than shown without departing from the scope of the various embodiments of the invention describe herein unless it is specifically stated otherwise.

Turning now to an overview of technologies that are more specifically relevant to aspects of the invention, ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. BEOL layers use insulating and stabilizing dielectric materials embedded with a network of wires, lines and vias (i.e., interconnects) that couple current to FEOL and MOL layers to complete the IC. The conductive interconnect layers formed during the BEOL stage serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metallization layers, complex ICs can have ten or more layers of wiring.

BEOL-stage interconnect structures that are physically close to FEOL-stage components (e.g., transistors and the like) need to be small because they attach/join to the components that are themselves very small and often closely packed together. These lower-level lines, which can be referred to as local interconnects, are usually thin and short in length. Global interconnects are higher up in the IC layer structure and travel between different blocks or cells of the circuit. Thus, global interconnects are typically thick, long, and more widely separated than local interconnects. Vertical connections between interconnect levels (or layers) are known as metal-filled (or conductive) vias and allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

In complex and dense ICs (e.g., high-speed very large scale integrated (VLSI) ICs), thousands to millions of transistors and other devices are present on a single chip, and these ICs/chips are configured to implement complex structures/functions, such as microprocessors, memory chips, or system-on-chip (SoC) designs. Because it is not practical or, under some circumstances, not possible to manually execute the design tasks (e.g., signal timing, metal density, signal integrity, and the like) required for acceptable design & manufacturing runtimes to create complex and dense ICs, software/hardware known as “electronic design automation” (EDA) tools have been developed to assist with the design of electronic systems.

EDA tools assist with a variety of electronic system design operations, including, for example, so-called “place and route” operations used in IC design. The terms “place and route” refer to design stages of electronic systems such as ICs and printed circuit boards (PCBs) that map out the placement of electronic components/circuitry, along with the routing of interconnect structures needed to connect the placed components/circuitry. As implied by the name, placement operations involve deciding where to place all electronic components, circuitry, and logic elements in a generally limited amount of space. An inferior placement assignment will not only affect the chip's performance but might also make it non-manufacturable by producing excessive wire-length, which is beyond available routing resources. Thus, the placement operation(s) must be performed while optimizing a number of objectives to ensure that a circuit meets its performance demands. Placement operations take a given synthesized circuit netlist together with a technology library and produces a valid placement layout. In electronic design, a netlist (or net) is a description of the connectivity of an electronic circuit. In its simplest form, a netlist includes a list of the electronic components in a circuit and a list of the nodes they are connected to. The layout is optimized according to the aforementioned objectives and made ready for cell resizing, as well as buffering operations operable to achieve timing and signal integrity satisfaction.

Placement operations are followed by routing operations, which decide the exact design of all the wires needed to connect the placed components. Routing operations build on placement operations to implement all the desired connections while following the rules and limitations of the manufacturing process. The portion of an EDA that performs routing operations is often referred to generally as a router. In general, routers are provided with some pre-existing polygons that represent pins (also called terminals) on cells, and optionally some pre-existing wiring called pre-routes. Each of the polygons is associated with a net, usually by name or number. The primary general task of the router is to create geometries such that all terminals assigned to the same net are connected, no terminals assigned to different nets are connected, and all design rules are obeyed. A router can fail by not connecting terminals that should be connected (an open), mistakenly connecting two terminals that should not be connected (a short), or creating a design rule violation. In addition, to correctly connecting the nets, routers can also ensure that the IC design meets timing, has no crosstalk problems, meets any metal density requirements, does not suffer from antenna effects, and so on. The objectives a router seeks to satisfy can be numerous and are often conflicting, which makes routing extremely difficult. Some routers, therefore, do not attempt to find an optimum result, but are instead based on heuristics, which try to find a solution that is good enough.

The electronic components/circuity of an IC design can be organized as cells with different functions. For example, cells can be logic gates (e.g., AND gates, OR gates, and the like), as well as combinational logic circuits (e.g., a multiplexer, a flip-flop, an adder, a counter, and the like). Cells can be selected and arranged to realize complex IC functions. To improve the efficiency of formulating IC designs, cell libraries can be established to include frequently used cells with their corresponding layouts. Therefore, when designing an IC, a designer can select desired cells from the library and place the selected cell in an automatic placement and routing block, such that a layout of the IC can be created.

In instances where there is a hierarchical relationship between IC/PCB components, the component that sets the requirements (e.g., timing requirements or other constraints) for another component is known as the “parent,” and the component that has its requirements (e.g., timing requirements or other constraints) set by another component is known as the “child. ” It is a priority in IC designs to re-use as many IC/PCB components as possible, which means that a given component is often deployed at multiple locations throughout the IC. The multiple locations can be within the same chip of the IC or across multiple different chips of the IC. Thus, a re-used component can be a child component to multiple different parent components, which means that the child components will need to satisfy multiple, potentially competing constraints that come from multiple different parent components.

Buffers are often added to an IC design to achieve timing and signal integrity satisfaction. In general, a buffer is a circuit that amplifies the current but leaves the voltage unchanged, thereby boosting the current capacity of a weak signal source so that it can drive a load. Buffers can be implemented in a variety of forms, including, for example, two inverters connected in series that invert and then reinvert a binary bit.

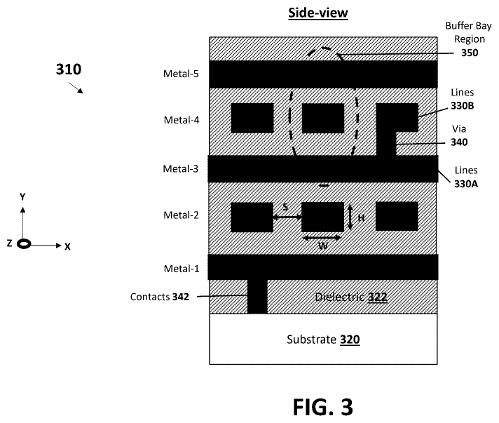

Buffer bays are areas in an IC design that are dedicated to buffers and interconnections that are multi hierarchical. Where child design buffer resources are shared with the parent design, in order to communicate this shared resource, blockages or blockage areas, are used within the buffer bay where placement of other cells or components is restricted or prohibited. These buffer bays have different resource allocation depending upon their orientation known as horizontal or vertical buffer bays. Additionally, the “top” of the buffer bay will change depending upon the maximum routing layer (ceiling) of the child design. In IC design, the “top” of the buffer bay typically refers to the first layer of the buffer bay which is above the child design ceiling and thus unblocked by the child resource allocation. The buffers or drivers in a buffer bay help manage signal integrity, drive strength, and timing, and for a connection to be made to buffers placed within a buffer bay, this must be done at the top of the buffer bay. Similarly, the “maximum routing layer” or “routing layer ceiling” of a child design refers to the highest level of metal layers available for routing signals in a design hierarchy of an IC/chip. For example, if the maximum routing layer is the 4th metal layer (e.g., Metal-4 shown in FIG. 3), this means that routing within the child design can utilize up to the 4th metal layer but no higher layers will be used. In practice, the maximum routing layer ceiling for a child design helps ensure that the child design fits within the available routing resources and adheres to the overall IC layout plan. IC routing must be aware of the connections within the buffer bays and the available resource provided.

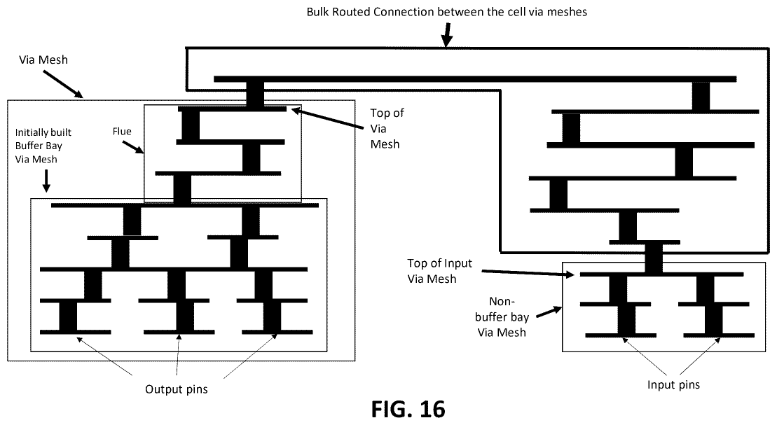

In IC design, a “flue” generally refers to a routing element or a specific design feature used to guide or manage the routing of interconnects. Flues provide structured pathways that help in optimizing the routing process and managing congestion. Because buffer bays focus on the placement of specific components (buffers) for performance enhancement, these components/buffers are routed with flues whose focus is on optimizing the routing of interconnects to ensure efficient layout and minimize congestion. A flue route as it pertains to aspects of the invention is the connection from the top of a via mesh to the top of the buffer bay. A via mesh provides multiple conductive pathways from one or more points in one layer to one or more points in another layer. A flue is an extension of the via mesh added in by the blockage aware router. Additional details of how flues are implemented in accordance with aspects of the invention are illustrated (e.g., at FIGS. 16B and 16C) and described subsequently herein.

As previously noted, the cells that make up an IC or a chip are interconnected to perform the overall functionality of the chip. Each cell involves an interconnection of components that, together, perform the function of that cell (e.g., logic gates, such as an AND gate, an OR gate, combinational logic circuits such as a multiplexer, a flip-flop, an adder, a counter, and the like). A via mesh provides multiple conductive pathways from one or more points in one IC layer to one or more points in another IC layer. At the first level, the via mesh includes interconnected shapes (i.e., wires and vias) that connect to a pin terminal formed from a single pin or a set of disjoint pins that are logically treated as one pin. On each subsequent IC layer, one or more straps, which are conductive strips, form conductive pathways that are connected to straps on adjacent IC layers through one or more vias. While the straps within an IC layer are oriented parallel to each other, the straps of adjacent layers can be oriented in a different (e.g., orthogonal) direction relative to each other or may be parallel. A router that connects one or more pins of the cell to pins of other cells, which may or may not include a via mesh, only connects to the strap at the highest level of the via mesh. The number of layers from the one or more pins to the highest level defines the height of the via mesh. The redundancy afforded by the straps and vias results in a reduction in resistance of the connection from the one or more pins to the upper layers. The number of straps and vias determines the resistance. A decrease in resistance is referred to as an increase in strength of the via mesh.

A via mesh specification provides a via mesh router with the required number of straps and vias for each metal layer of the cell. In other words, a via mesh specification defines the via mesh structure and indicates the via mesh height. A given cell can have more than one via mesh specification associated with it, and each via mesh specification can offer a different resistance and corresponding strength.

A universally routable via mesh specification library can be provided to place and route tools to facilitate the selection of the via mesh specification based upon the cell and the net requirements. A universally routable via mesh specification library can be created through a methodology by which cells are analyzed and grouped based upon certain characteristics including cell dimensions and terminal pin counts, then via mesh specifications are defined which are guaranteed to be routable for the cell group.

Although buffer bays and via-mesh interconnect designs each have technical benefits, existing techniques for building via-mesh interconnects do not enable via-mesh interconnects to be built inside of buffer bays because, with the required buffer bay blockages, the number of vias require by via mesh designs, and other factors, known via mesh design methodologies cannot build via meshes that can fit inside buffer bays taking into account the various blockage patterns assigned to the given buffer bay. Accordingly, incorporating both via-mesh interconnect designs and buffer bay designs into an IC design requires that any cell requiring a via-mesh design is limited to being located outside the buffer bays and their associated buffer bay blockage areas.

Routing the assigned via mesh specifications from the universally routable via mesh specification library and the interconnections through buffer bay blockages for the buffers/interconnects inside the buffer bay is made difficult by several factors. For example, buffer bay blockages break existing routing methodologies (i.e., buffer bay blockages don't adhere to the routing methodology), resulting in failed via mesh construction where the via mesh does not meet the via mesh specification, thereby creating a discrepancy in the timing correlation between placement and routing.

Additionally, the via meshes that are constructed will not route to the top of the buffer bay, requiring the insertion of an additional routing connection which can navigate the buffer bay blockage to the top of the buffer bay. This additional connection from the top of the via mesh, or the pin terminal if a via mesh is not required, to the top of the buffer bay is referred to as a “flue” connection. Thus, known routing techniques make routing through buffer bays (and their associated buffer bay blockages) challenging and time consuming.

Additionally, in order for interconnects/buffers inside the buffer bays to connect to and take advantage of the technical benefits provided by via-mesh interconnect designs, routing techniques must be developed that route the buffers and/or interconnects inside a buffer bay area through the buffer-bay blockages, and new via-mesh specifications must be generated and assigned to allow the routed buffer bay via mesh to satisfy the IC design's timing and electrical characteristic requirements, taking into account the additional restrictions imposed on the via-mesh design by having to route the via-mesh design through the buffer bay blockages. Using manual interconnect routing techniques and via-mesh design techniques to satisfy the above-described need is impractical due to the high complexity, precision requirements, runtime requirements, and optimization needs of modern ICs. Thus, there is a need for EDA routing tools that efficiently and accurately manage the intricate and dense routing required in dense and complex IC designs that seek to leverage the technical benefits of buffer bays (with defined blockage areas) and via-mesh interconnect designs.

Embodiments of the invention provide computing systems, computer-implemented methods, and computer program products that implement an EDA tool and IC design router configured and arranged to perform “blockage aware” interconnect routing in buffer bays of an IC design. In some embodiments of the invention, the IC design router is configured to take into account the existence of via-mesh interconnect designs in the IC design. The novel IC design router disclosed herein is aware of buffer bay blockage regions and provides a routing solution that enables via-mesh interconnect designs to be built into the IC design in a way that enables the timing-related and electrical-characteristic-related technical benefits associated with via-mesh interconnect designs to be leveraged, including specifically the improved RC characteristics that can be inserted into the IC design through the design of the via-mesh.

In embodiments of the invention, a novel EDA tool and associated router are provided and configured to perform operations that include receiving or accessing an electronic representation of an IC design, identifying information (e.g., location, blockage pattern(s), dimensions, shape, etc.) of the buffer bays in the IC design, analyzing the blockage pattern(s) of each buffer bay to understand the different blockages that are in place to determine how high the buffer bay is built to, and classifying the blockage pattern(s) of each buffer bay. The novel EDA tool is further configured to utilize the classified blockage pattern(s) of each buffer bay to update the assigned via mesh specification (by assigning an appropriate pin constraint) to one that is routable through the blockage pattern for the buffers/interconnects while satisfying the RC characteristics required by the IC design. The associated via-mesh interconnect design that routes through blockages to buffers/interconnects inside buffer bays are referred to herein as buffer-bay via-mesh designs, while the via-meshes of the IC design that do not route directly through blockages to buffers/interconnects inside buffer bays are referred to herein as simply via-mesh designs. The novel EDA router is further configured to extend the buffer-bay via-mesh interconnect design to provide access points for the router above the buffer bay. In embodiments of the invention, when moving from outside a buffer bay to inside a buffer bay, the IC design can switch from via-meshes to an appropriate one of the one or more buffer-bay via-meshes.

Thus, embodiments of the invention provide a separate process for specialized “buffer-bay routing” within a buffer bay as opposed to bulk routing. In IC design routing, “bulk routing” refers to the process of creating extensive or large-scale routing paths across the IC. Bulk routing involves laying down significant portions of the metal interconnects across the IC/chip to connect various components, such as standard cells or functional blocks, over large areas. Bulk routing is a broad and foundational aspect of the routing process, setting up the primary pathways for signal, power, and ground connections. Bulk routing provides the initial framework for more detailed and specific routing tasks and establishes the primary channels that will be refined and optimized in later stages. By addressing large areas and major routing channels early, bulk routing helps manage congestion and ensures that there is enough space for subsequent, more detailed routing.

Thus, as summarized above, and as described in greater detail in this detailed description, embodiments of the invention provide technical effects and technical benefits. For example, embodiments of the invention provides systems and computer-implemented methods of identifying buffer bays and the buffers placed within then, switching the assigned via mesh specification to one which is routable through the buffer bay blockage, finding a routing path through the buffer bay blockage and extending the via mesh with a flue to the top of the buffer bay. This allows for seamless integration of buffer bays into the bulk routing methodology, requiring no further adaptation of the tools to handle buffer bays.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

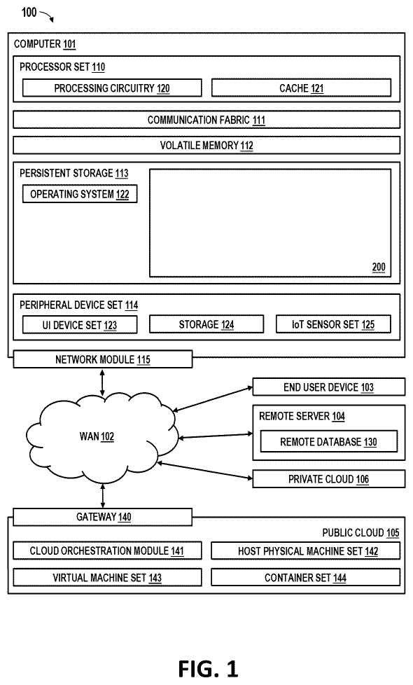

FIG. 1 depicts a computing environment 100 that contains an example of an environment for the execution of at least some of the computer code involved in performing the inventive methods, such as code block 200 operable to implement the novel EDA tool with blockage aware buffer bay routing features described herein. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

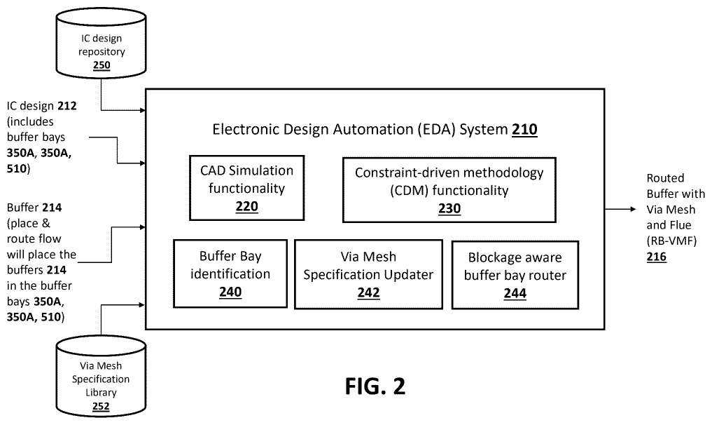

Turning now to a more detailed description of aspects of the invention, due to the large number of components and the details required by the fabrication process for VLSI ICs, physical design is not practical without the aid of computers. As a result, most phases of physical design extensively use EDA tools (EDA system 210 shown in FIG. 2) or computer-aided design (CAD), and many phases have been partially or fully automated. Automation of the physical design process has increased the level of integration, reduced turn-around time, and enhanced chip performance. The processes associated with developing the IC/chip (e.g., IC design 212 shown in FIG. 2) include obtaining an electronic version of the IC/chip design, which can in some embodiments of the invention be implemented as a register transfer level (RTL) description and performing physical design to identify and place components such as gate logic. The physical design processes generally begin with logic synthesis, which maps the RTL description to a gate-level netlist (i.e., list of logical interconnects or nets), and end with tape-out and mask generation, which refers to turning the design data into photomasks that are used in the manufacturing process. The physical design processes also include routing, which refers to adding the wires that connect gates and other components to implement the nets of the netlist. Several different programming languages have been created for EDA tools, including Verilog, very high-speed IC hardware description language (VHDL) and test description and markup language (TDML). A typical EDA tool/system (e.g., EDA system 210 shown in FIG. 2) receives one or more high level behavioral descriptions of an IC device (e.g., IC design 212 shown in FIG. 2) information of buffers (e.g., buffers 214 shown in FIG. 2), and translates this high level design language description into netlists of various levels of abstraction.

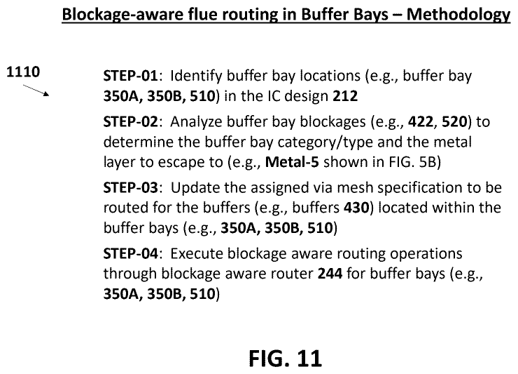

FIG. 2 depicts a non-limiting example of an EDA system 210 that can be used to implement aspects of the invention. The EDA system 210 can be implemented using any appropriate combination of the features and functionality of the computing environment 100 (shown in FIG. 1). The EDA system 210 includes computer-aided design (CAD) simulation functionality 220, constraint-driven methodology (CDM) functionality 230, buffer bay identification functionality 240, via mesh specification updater functionality 242, and blockage aware buffer bay router functionality 244, configured and arranged as shown. The CDM functionality 230, the buffer bay identification functionality 240, the via mesh specification updater functionality 242, and the blockage aware buffer bay router functionality 244, cooperate to perform operations defined by a computer-implemented methodologies embodying aspects of the invention, including specifically the computer-implemented methodologies 1110, 1210, 1310, 1410, 1510 shown in FIGS. 11, 12, 13, 14, 15, which are described in greater detail subsequently herein.

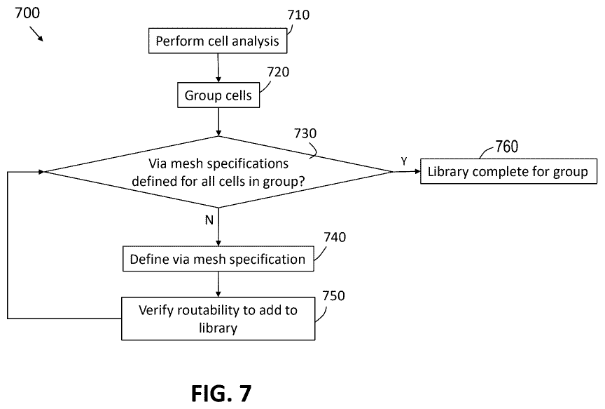

The EDA system 210 is coupled to an IC design repository 250 and a via mesh specification library 252. The IC design repository 250 is configured to store electronic information about various aspects of IC designs, including dimensions, shapes, materials, placements, and general performance characteristics. The via mesh specification library 252 is operable to facilitate the selection from the via mesh specification library 252 of an appropriate via mesh specification based upon the cell and the net requirements. The via mesh specification library 252 can be created through a methodology (e.g., methodology 700 shown in FIG. 7) by which cells are analyzed and grouped based upon certain characteristics including cell dimensions and terminal pin counts, then via mesh specifications are defined which are guaranteed to be routable for the cell group.

In embodiments of the disclosure, the EDA system 210 includes CAD simulation functionality 220. CAD is the use of computer-based software to aid in design processes. CAD software is used by engineers and designers to create two-dimensional (2D) drawings or three-dimensional (3D) product-under-development (PUD) models. A purpose of CAD is to optimize and streamline the designer's workflow, increase productivity, improve the quality and level of detail in the design, improve documentation communications, and often contribute toward a manufacturing design database. CAD software outputs can be in the form of electronic files, which are used for manufacturing and/or fabrication processes. CAD can be used in tandem with digitized manufacturing/fabrication processes known as computer-aided manufacturing (CAM) processes. CAD/CAM software can be used to design a variety of products such as electronic circuit boards in computers and other devices. The CAD simulation functionality 220 allows virtual experiments to be performed on an electronic version of the IC design 212 instead of a physical prototype of the IC design 212.

The CDM functionality 230 is a design and optimization approach used in the IC design operations performed by the EDA system 210. The CDM functionality 230 focuses on leveraging constraints to guide the design process and ensure that the final IC meets specified performance, power, area, and timing requirements. The EDA system 210 uses the CDM functionality 230 to use the constraints to drive the design process, making adjustments as needed to ensure that the final design adheres to the defined specifications. The design process is iterative, involving multiple rounds of optimization and verification. Constraints are continuously checked and updated as the design evolves. Constraints are propagated through different stages of the design flow. For example, timing constraints might influence the placement of components and routing of signals to ensure that data paths meet timing requirements. By automating the design process and focusing on constraints, the CDM functionality 230 streamlines design efforts and reduces manual intervention, leading to more efficient development. Thus, the CDM functionality 230 is a systematic approach to IC design that emphasizes the use of constraints to guide and optimize the overall design processes performed by the EDA system 210. By leveraging automation tools, iterative optimization, and continuous verification, the CDM functionality 230 can achieve high-performance, reliable, and efficient designs while managing trade-offs and ensuring all IC design requirements are met.

In some embodiments of the invention, the above-described constraints are developed using historical data about relevant portions of historical IC designs stored in the IC design repository 250. In some embodiments of the invention, the above-described constraints are developed using historical data about relevant portions of historical IC designs stored in the IC design repository 250, along with relevant via mesh specifications in the via mesh specification library 252. In some embodiments, for the IC design repository 250 and/or the via mesh specification library 252, the repository and/or the library can be implemented as a searchable database operable to organize and store data/information of activities and/or events of the historical data about IC designs and/or via mesh specifications in segments or regions of the IC design repository 250 and/or the library 252. The IC design repository 250 and/or the via mesh specification library 252 (i.e., repository/library 250, 252) can be any form of database, including but not limited to, relational SQL databases, noSQL unstructured databases, unstructured data lakes, time-series databases, and the like. In some embodiments, the repository/library 250, 252 can include features and functionality of a relational database operably controlled by the computing environment 100 (shown in FIG. 1). In general, a database is a means of storing information in such a way that information can be retrieved from it, and a relational database presents information in tables with rows and columns. A table is referred to as a relational table in the sense that it is a collection of objects of the same type (rows). Data in a table can be related according to common keys or concepts, and the ability to retrieve related data from a table is the basis for the term relational database. A database management system (DBMS) of the computing environment 100 controls the way data in the IC design repository 250 and/or the via mesh specification library 252 are stored, maintained, and retrieved. A database management system of the computing environment 100 performs the tasks of determining the way data and other information are stored, maintained, and retrieved from the IC design repository 250 and/or the via mesh specification library 252.

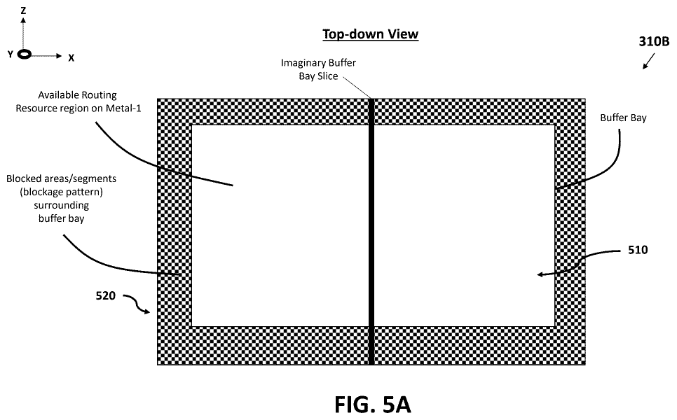

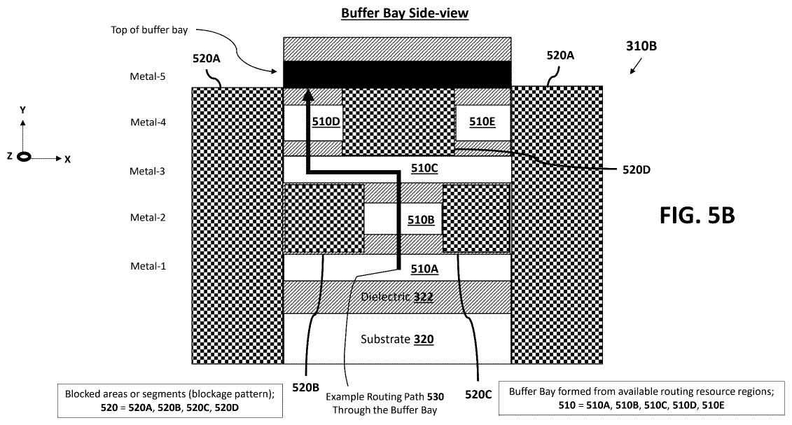

In some embodiments of the invention, the EDA system 210 is operable to utilize cognitive algorithms (not shown separately from the EDA system 210) to perform the various data analysis and simulation/prediction operations described herein. In embodiments of the disclosure, a cognitive algorithm refers to a variety of algorithm types (e.g., machine learning and/or artificial intelligence algorithms) that generate and apply computerized models to simulate the human thought process in complex situations where the answers might be ambiguous and uncertain. A conventional cognitive algorithm includes self-learning technologies that use data mining, pattern recognition, natural language processing (NLP), and other related technologies to generate the mathematical models that make decisions (e.g., classifications, predictions, and the like) that, in effect, mimic human intelligence. In embodiments of the disclosure, the modifier “cognitive” as applied to “outputs” and/or “output actions” refers to the outputs, actions, and the like generated by cognitive algorithms to represent the result of the analysis operations performed by cognitive algorithms. A non-limiting example of a cognitive output action is analyzing buffer bay blockages to determine an appropriate escape layer (i.e., one or more blockage area exit locations) (e.g., STEP-02 shown in FIG. 11). Another non-limiting example of a cognitive output action is predicting, updating, and/or optimizing the assigned via mesh specification to be routed for the buffers located within a buffer bay (STEP-03 shown in FIG. 11). Still another non-limiting example of a cognitive output action is predicting and/or optimizing a blockage aware routing (e.g., routing path 530 shown in FIG. 5B) from a specially designed via mesh through buffer bay blockages to buffers in a buffer bay (e.g., STEP-04 shown in FIG. 11).

In accordance with embodiments of the invention, the EDA system 210, and more specifically the CDM functionality 230 working in tandem with the buffer bay identification functionality 240, the via mesh specification updater functionality 242, and blockage aware buffer bay router functionality 244, using the operations described above generate a routed buffer with via mesh and flue (RB-VMF) 216 that results from performing “blockage aware” interconnect flue routing in buffer bay regions of the IC design 212 in accordance with aspects of the invention. In embodiments of the invention, the EDA system 210 (using the buffer bay identification functionality 240, the via mesh specification updater functionality 242, and blockage aware buffer bay router functionality 244) is configured to perform operations that include receiving or accessing an electronic representation of an IC design 212, identifying information (e.g., location, blockage pattern(s), dimensions, shape, etc.) of the buffer bays in the IC design 212, analyzing the blockage pattern(s) of each buffer bays to understand the different blockages that are in place to determine how high the buffer bay is built to, and classifying the blockage pattern(s) of each buffer bay. The EDA system 210 is further configured to utilize the classified blockage pattern(s) of each buffer bay to generate the RB-VMF 216, which includes associated via-mesh interconnect designs that connect through the blockages to the buffers 214 (and/or interconnects) using a buffer-bay routing plan while satisfying the RC characteristics required by the IC design 212. The associated via-mesh interconnect design that routes through blockages to buffers 214 (and/or interconnects) inside buffer bays are referred to herein as buffer-bay via-mesh designs, while the via-meshes of the IC design 212 that do not route directly through blockages to buffers 214 (and/or interconnects) inside buffer bays are referred to herein as simply via-mesh designs. The EDA system 210 and blockage aware buffer bay router functionality 244 are further configured to extend the buffer-bay via-mesh design to provide access points above the buffer bay. In embodiments of the invention, when moving from outside a buffer bay to inside a buffer bay, the IC design 212 can switch from via-meshes to an appropriate one of the one or more buffer-bay via-meshes.

Thus, the EDA system 210 provides a separate process for specialized “buffer-bay routing” within a buffer bay as opposed to bulk routing. In IC design routing, “bulk routing” refers to the process of creating extensive or large-scale routing paths across the IC. Bulk routing involves laying down significant portions of the metal interconnects across the IC/chip to connect various components, such as standard cells or functional blocks, over large areas. Bulk routing is a broad and foundational aspect of the routing process, setting up the primary pathways for signal, power, and ground connections. Bulk routing is a multi-step process which establishes detailed connections to all the pins which make up the net connection. Bulk routing expects the design to follow a set of design methodologies to assure the pin connections are routable. As previously described herein, this is not the case in buffer bays, and as a result a specialized router is required to route through the buffer bay blockages to the top of the buffer bay to allow for bulk routing to establish the connection.

FIG. 3 depicts a simplified block diagram illustrating a side view of an IC 310 (e.g., a VLSI IC) having a horizontal buffer bay region 350 extending over metal layers Metal-3, Metal-4, Metal-5 that can be designed and routed using the EDA system 210 (shown in FIG. 2) in accordance with embodiments of the invention. It should be understood that, although the cross-sectional diagrams depicted herein (including but not limited to the diagrams shown in FIGS. 3, 4, 5A, 5B) are two-dimensional, the diagrams depicted herein are three-dimensional structures extending along a Y-axis, an X-axis, and a Z-axis, which are represented by the X/Y/Z axes depicted in these figures.

The IC 310 includes a substrate 320 (e.g., formed from silicon), multiple dielectric layers or regions 322, a network of contacts 342 (for ease of illustration, only one contact is shown), a network of metal lines 330A extending along the X-axis, a network of metal lines 330B extending along the Z-axis, and a network of vias 340 (for ease of illustration, only one via is shown), configured and arranged as shown. Sample line-related dimensions are shown, including S (space between metal lines), W (width of each metal line), and H (height of each metal line). Five metal layers of the IC 310 are shown and include Metal-1 (lowest layer), Metal-2, Metal-3, Metal-4, Metal-5 (highest layer).

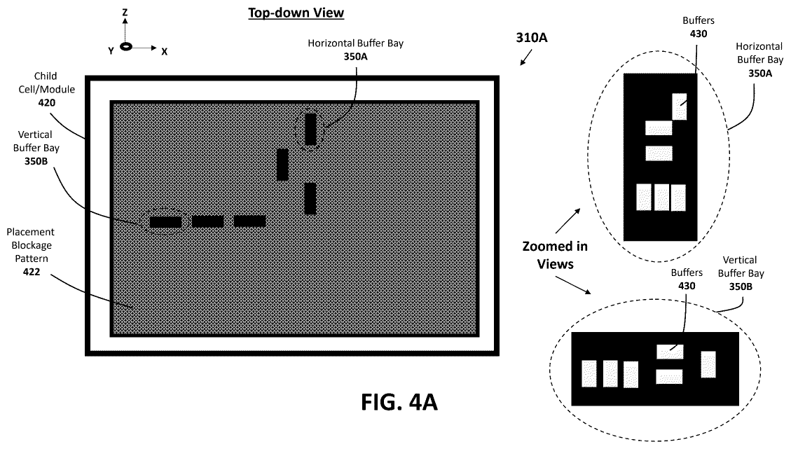

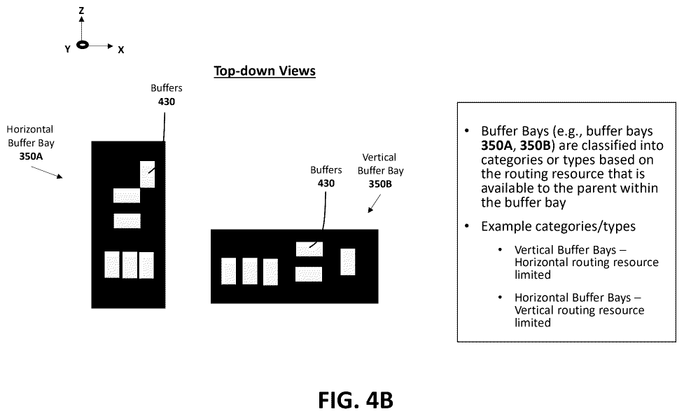

The metal layers metal layers (Metal-1, Metal-2, Metal-3, Metal-4, Metal-5) are used for various purposes, primarily for interconnecting different components and creating the required circuit paths. The most visible metal layers are located near the top surface of the IC 310. These are the layers typically formed in the BEOL or final stages of the IC chip design process. The metal layers are situated between different instances of the dielectric layers or regions 322. The first level metal layer (Metal-1) is directly above the substrate 320 and is often used for connecting transistors within a small area. The subsequent metal layers (Metal-2, Metal-3, Metal-4, Metal-5) are used for routing signals between different parts of the IC 310 and connecting to various components. Each layer is separated by dielectric layers or regions 322 to prevent electrical shorting between the metal layers. A buffer bay region 350 is identified by the IC design 212 (shown in FIG. 2). The buffer bay region 350 represents a side-view of a region in which a buffer bay (not shown in FIG. 3) can be located. A buffer bay in the buffer bay region 350 can have a horizontal orientation (e.g., horizontal buffer bays 350A shown in FIGS. 4A and 4B) and/or a vertical orientation (e.g., vertical buffer bay 350B shown in FIGS. 4A and 4B).

The IC 310 is a hierarchical design including cell/module regions (not shown separately) organized as parent cells and child cells. The parent-child cell/module relationship in the IC 310 reflects a hierarchical and functional decomposition where the parent module integrates and manages child modules to create a complete and functional design. The parent cell/module is the higher-level cell/module in the IC design hierarchy. The parent cell/module encompasses a larger portion of the IC 310 and is responsible for integrating various sub-modules to form a complete functional unit. The child cell/module is a lower-level module within the parent cell/module used to achieve the parent's overall functionality. For example, a parent cell/module can represent a complex subsystem like a microprocessor, and the microprocessor could be made up of child modules like arithmetic logic units (ALUs), registers, and cache controllers.

The parent cell/module interfaces with its child modules through defined ports or signals. These interfaces dictate how data and control signals are passed between the parent and child cells/modules. Properly defining these interfaces ensures that the child cells/modules interact correctly within the parent cell/module.

Embodiments of the invention, as described in this detailed description, provide systems and methods for controlling the “resources” that are provided to a parent cell/module from a child cell/module. In the routing stage of designing the IC 310 (e.g., using, for example, the IC design 212), “resources” from a child cell/module to a parent cell/module generally refer to design data and information that facilitate the integration and optimization of the IC 310. Such resources can include routing data (e.g., netlist information, placement data, etc.), design constraints (e.g., design rules, timing constraints, etc.), routing constraints (e.g., layer usage, congestion areas, etc.), electrical characteristics (e.g., resistance and capacitance information; signal integrity requirements; and the like), design hierarchy information (e.g., hierarchical relationships, interface specification, etc.), design and verification data (e.g., design verification results, design changes, design updates, etc.), and integration information (e.g., integration constraints, etc.).

More specifically, for netlist information, the netlist includes the list of electrical connections between different components in the child cell/module. This information helps the parent cell/module understand how to integrate these connections into the overall design of the IC 310. For placement data, the positions of components within the child cell/module are provided, which can be used to determine the layout of interconnects (e.g., metal lines 330A, 330B, vias 340). For design rules, constraints related to line spacing(S), line width (W), line height (H) and other design rules specific to the child cell/module are passed up to the parent cell/module. These constraints ensure that the routing in the parent cell/module adheres to the required design specifications.

For timing constraints, information about critical paths and timing requirements within the child cell/module helps the parent cell/module meet overall performance goals. For metal layer usage, information on the metal layers used within the child cell/module and their specific routing needs is communicated to the parent cell/module. This includes details on layer assignments for different types of interconnects. For congestion areas, information on areas where routing congestion is anticipated within the child cell/module is passed to the parent cell/module. This helps the parent cell/module manage and plan routing to avoid conflicts. Data on electrical characteristics of the interconnects in the child cell/module, such as capacitance and resistance, is provided to manage signal integrity and ensure that the overall IC design meets electrical performance requirements.

For signal integrity requirements, information about signal integrity concerns, such as crosstalk or noise issues, is shared with the parent cell/module to ensure that these issues are addressed in the broader IC design. For hierarchical relationships, details about the hierarchical structure of the IC design, including how child cells/modules fit into the parent cell/module, are provided. This helps in understanding how routing in the child cell/module impacts the parent design. For interface specifications, information on the interfaces between child cells/modules and the parent cell/module, including connection points and required routing paths, is communicated. For design verification results, any verification or validation results from the child cell/module are provided to the parent cell/module. This includes information about rule violations or issues detected during verification. For design changes and updates, changes/updates made in the child cell/module during the design process are communicated to the parent cell/module, ensuring that the parent cell/module reflects the latest design modifications. For integration constraints, specific constraints related to how the child cell/module integrates with the parent cell/module, such as alignment or connectivity constraints, are provided.

FIGS. 4A and 4B depict simplified block diagrams illustrating top-down views of an IC 310A (e.g., a VLSI IC) having horizontal buffer bays 350A and vertical buffer bays 350B that can be designed and routed using embodiments of the invention. In general, buffer bays can be classified into categories based on the routing resource that is available to the parent cell(s) of the IC within the buffer bay. The horizontal orientation of the horizontal buffer bays 350A means that vertical routing resource of each horizontal buffer bay 350A are limited The vertical orientation of the vertical buffer bays 350B means that horizontal routing resource of each vertical buffer bay 350B are limited. FIGS. 4A and 4B also depict zoomed-in views illustrating additional details of an instance of the horizontal buffer bays 350A and an instance of the vertical buffer bays 350B, each of which includes a configuration of buffers 430 (or buffer circuitry). As best shown in FIG. 4A, the top-down view of the IC 310A further depicts a child cell/module 420, along with a non-limiting example of a placement blockage pattern 422 configured to define regions associated with the horizontal buffer bays 350A and the vertical buffer bays 350B. The blockage pattern 422 defines one or more areas of the IC 310A that are “reserved” such that no interconnect structures can be located in the blockage pattern 422 (i.e., the “reserved” areas) using the portion of the design of the IC 310A that places and routes the multiple instances of the buffer bays 350A, 350B. Additional details of how the placement blockage pattern 422 can be implemented are depicted in FIGS. 5A and 5B as the blocked area 520, which is formed from individual blocked area segments 520A, 520B, 520C, 520D, 520E, configured and arranged as shown. Additional details of how the buffer bays 350A, 350B can be implemented are depicted in FIGS. 5A, 5B as the available routing resources 510, which are formed from individual available wiring resources 510A, 510B, 510C, 510D, 510E. FIGS. 5A and 5B are described in greater detail subsequently herein.

The placement blockage pattern 422 is used to manage the placement and routing of the multiple instances of the buffers 430 within the IC 310A. The buffers 430 are used to drive signals across long distances, ensure signal integrity, and match impedances. However, placing too many buffers 430 or not managing their placement properly can lead to signal integrity issues or excessive power consumption. The blockage pattern 422 is configured in a manner that helps manage the space and ensure that the design of the IC 310A remains efficient. By controlling where the buffers 430 can and cannot be placed, designers can better plan the layout and routing of other components. The blockage pattern 422 defines the shape and location of the multiple instances of the horizontal buffer bays 350A and the multiple instances of the vertical buffer bays 350B. The buffer bay blockage pattern 422 can be implemented and enforced through design rule checks (DRCs) in the EDA system 210 (shown in FIG. 2). These rules ensure that the placement and routing of the buffers 430 adhere to the specified constraints. Designers can specify custom blockage patterns (e.g., the locations, shapes and spacings of the individual blockage areas 520A, 520B, 520C, 520D, 520E shown in FIG. 5B) based on the specific requirements of the IC design, such as signal timing, power distribution, and thermal management.

FIG. 5A depicts a simplified block diagram illustrating a top-down view of a portion of an IC 310B (e.g., a VLSI IC), and FIG. 5B depicts a cross-sectional side-view of the IC 310B shown in FIG. 5A. Buffer bay routing can be applied to the IC 510B using the blockage aware buffer bay routing features described herein in accordance with embodiments of the invention. The IC 310B shown in FIG. 5A depicts an example buffer bay 510 and a surrounding set of associated blocked areas/segments (or blockage patten(s)) 520 shown on the Metal-1 layer. The buffer bay 510 defines a configuration of available routing resource regions 510, and the blocked areas/segments (or blockage pattern) 520 define a configuration of blocked areas/segments 520. On the Metal-1 layer, no such blockage exists over the buffer bay as indicated by the full coverage of the available routing resource region 510 over the top-down area of the buffer bay (or available routing resource region) 510. However, because portions of the blocked areas/segments 520 surround the portion of the buffer bay (available routing resource region) 510 at Metal-1 layer, there exists surrounding blockage of the buffer bay 510 which prevents connections or routing from being made from a component (e.g., an instance of the buffers 430 shown in FIGS. 4A and 4B) inside the available routing resource region (e.g., 510A shown in FIG. 5B) directly to the Metal-1 layer outside the buffer bay 510. An imaginary slice is made into this buffer bay 510 to depict the buffer bay side-view shown in FIG. 5B. As best shown in FIG. 5B, the buffer bay region 510 represents an example horizontal buffer bay (e.g., horizontal buffer bay 350A shown in FIGS. 4A and 4B). As best shown in FIG. 5B, the buffer bay 510 will extend across multiple the metal layers (Metal-1, Metal-2, Metal-3, Metal-4, Metal-5) up to the ceiling of the child module (e.g., child cell/module 420 shown in FIG. 4A). As previously noted herein, the ceiling of the child module represents the “routing layer ceiling” or “maximum routing layer”, which refers to the highest level of metal layers available for routing signals in a design hierarchy of an IC/chip.

Referring more specifically to FIG. 5B, there is depicted a side view of the IC 310B, where the side view is taken along the imaginary buffer bay slice shown in FIG. 5A. Similar to the IC 310 depicted in FIG. 3, the IC 310B as depicted in FIG. 5B includes a substrate 320, dielectric layers or regions 322, and one or more instances of the lines 330A corresponding to Metal-5 at a top of the buffer bay 520. The one or more instances of the lines 330A correspond to Metal-5 at a top of the buffer bay 520 and represent one or more blockage area exit locations for routing paths (e.g., routing path 530) to navigate through the available routing resources regions 510A, 510B, 510C, 510D, 510E to exit the buffer bay 510 (best shown in in FIG. 5A). The blocked areas 520 in FIG. 5A are represented in the side view shown in FIG. 5B as various blocked areas or segments 520A, 520B, 520C, 520C, 520D, configured and arranged in a blockage pattern. The buffer bay 510 is formed from the available routing resources regions (or buffer bay regions) 510A, 510B, 510C, 510D, 510E, configured and arranged to form a pattern of the available routing resources regions (or buffer bay regions) 510A, 510B, 510C, 510D, 510E. In embodiments of the invention, various routing paths through the buffer bay 510 are defined with reference to just the various blocked areas or segments 520A, 520B, 520C, 520C, 520D; just the available routing resources regions 510A, 510B, 510C, 510D, 510E; or the various blocked areas or segments 520A, 520B, 520C, 520C, 520D in combination with the available routing resources regions 510A, 510B, 510C, 510D, 510E.

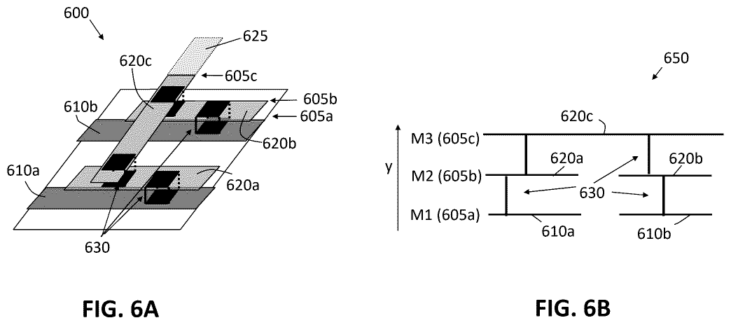

As illustrated by the non-limiting example depicted in FIG. 5B, the metal layers include from Metal-1 to Metal-5. Metal-1 through Metal-4 are surrounded by a blocked area or segment 520A, which prevents routing connections from being made to net elements outside of the buffer bay 510, thereby requiring a connection to be made from the layers above the blocked area or segment 520A. At layer Metal-5 the top of the buffer bay 510 is reached, where the surrounding blockage area or segment 520A is no longer present, thereby providing buffer bay exit location through which a routing path (e.g., routing path 530) can exit the buffer bay 510 and make routing connections to elements outside of the buffer bay 510. The positions of the available wiring resource regions 520B, 520C, 520D vary by layer from Metal-1 to Metal-5, by which a routing path (e.g., routing path 530) can be established from the buffers (e.g., an instance of the buffers 430 shown in FIGS. 4A and 4B) that exist in the buffer bay 510 to the top of the buffer bay 510. On Metal-2 and Metal-4, blocked areas or segments 520B (for Metal-2), 520C (for Metal-2), 520D (for Metal-4) denote blockages which represent an allocation of resources for the child cell, by which the parent level routing connection cannot use and must avoid. An example routing path 530 is shown which navigates the buffer bay blockage pattern from Metal-1 to the top of the buffer bay on Metal-5. Embodiments of the invention, as described in greater detail subsequently herein, provide computer-implemented methods that utilize (or take into account) information (e.g., location, size, shape and the like) of the various blocked areas or segments 520A, 520B, 520C, 520C, 520D to generate the various routing paths (e.g., routing path 530) to rout from components (e.g., instances of the buffers 430 shown in FIGS. 4A and 4B) placed in one of the available routing resources regions (or buffer bay regions) 510A, 510B, 510C, 510D, 510E FIGS. 6A and 6B depict an exemplary implementation of the via mesh 600 (shown in FIG. 6A) for an exemplary cell and a corresponding representation associated with the via mesh specification 650 (shown in FIG. 6B) that is generated and utilized according to one or more embodiments of the invention. It should be noted that the via mesh 600 has been simplified for ease of illustration. In practice, the via mesh 600 can include multiple layers of metal straps and multiple layers of conductive vias between the metal straps. The metal straps can not only be more numerous than illustrated, but can have a width of one to five times the minimum allowed wire width, and have varying lengths which can be as long as the diameter of the bounds of the electrical circuit of the pin. The spacing between adjacent straps can also be very small, typically on the order of the minimum allowed wire width.

FIG. 6A depicts a three-dimensional representation of the via mesh 600. Pins 610a, 610b (generally referred to as 610) are shown on the first layer 605a (generally referred to as 605). Straps 620a, 620b (generally referred to as 620) are shown on the second layer 605b. As FIG. 6A indicates, the pins 610 and straps 620 are parallel and a via 630 connects each pin 610 to a corresponding strap 620. As previously noted herein, the pins 610 and straps 620 on adjacent layers can be oriented differently (e.g., orthogonal), instead. Another strap 620c is shown at the third layer 605c, which is the top layer of the exemplary via mesh 600. The strap 620c on the third layer 605c is orthogonal to the straps 620a, 620b on the second layer 605b. The number of layers 605 defines the height of the via mesh 600.

Vias 630 facilitate a connection between the pins 610 on the first layer 605a and the straps 620 a and 620b on the second layer 605b and additional vias 630 facilitate a connection between each of the straps 620a and 620b on the second layer 605b and the strap 620c at the third layer 605c. The straps 620 and vias 630 make up the via mesh 600. A routing tool, referred to as a router, connects the pins 610 of the cell, through the via mesh 600 of the cell, to one or more other cells through a net associated with the IC design. Specifically, the router connects the to the net only at the top level 605 (i.e., the third layer 605c in the example shown) at the access 625. As previously noted herein, the via mesh 600 (e.g., the straps 620 and vias 630) provides redundancy in the connection from the net to the pins 610. Increased redundancy is proportional to increased strength of the via mesh 600 and decreased resistance.

FIG. 6B shows a representation of a via mesh specification 650 that is generated for the exemplary via mesh 600 shown in FIG. 6A according to one or more embodiments of the invention. The via mesh specification 650 defines the structure of the via mesh 600 and provides the router with wire and via counts for each layer 605. The exemplary via mesh specification 650, as represented in FIG. 6B, indicates that there are two pins 610 on the first layer 605a (i.e., metal layer 1 (M1)) that are connected by respective vias 630 to two straps 620 on the second layer 605b (i.e., metal layer 2 (M2)). Additional vias 630 allow a strap 620c on the third layer 605c (i.e., metal layer 3 (M3)) to connect to both straps 620 on the second layer 605b and, thereby, to both pins 610 on the first layer 605a. The number of straps 620 (2) on M2 and the number of straps 620 (1) on M3 can be used to represent the via mesh specification 650 as {2,1}. This indicates the number of metal layers and, thus, the height of the via mesh 600 as being 3, and also specifies the number of straps 620 on the second and every subsequent layer 605. As previously noted, exemplary embodiments of the invention relate to generating a library (e.g., via mesh specification library 652) of via mesh specifications 650 that are each guaranteed to be routable regardless of the placement of the cell that is associated with the via mesh 600. This routability is further discussed with reference to FIGS. 7-9.

FIG. 7 is a process flow of a methodology 700 of generating universally routable via mesh specifications 650 according to embodiments of the invention. At block 710, performing cell analysis refers to gathering statistics for each via mesh 600 of a cell including the number of input terminals, the number of input pins 610, the number of output terminals, the number of output pins 610, the cell width, and the cell height. A pin terminal refers to the logical representation of one or more pins 610. That is, a pin terminal can represent a single pin 610 or a disjoint set of pins 610 that are logically treated as one. At block 720, the grouping of cells can be based on different cell statistics. For example, the cells can be grouped according to the number of output pins 610 versus the cell height, the number of input pins 610 versus the cell height, or the number of output terminals versus the number of input terminals. At block 730, a determination is made whether via mesh specifications 650 were defined for the group in consideration of all the cells of the group. If so, then the methodology 700 ends at block 760 with a complete library of via mesh specifications 650 that are compatible with any of the cells of the group. If not, the processes at blocks 740 and 750 are performed iteratively, as indicated.

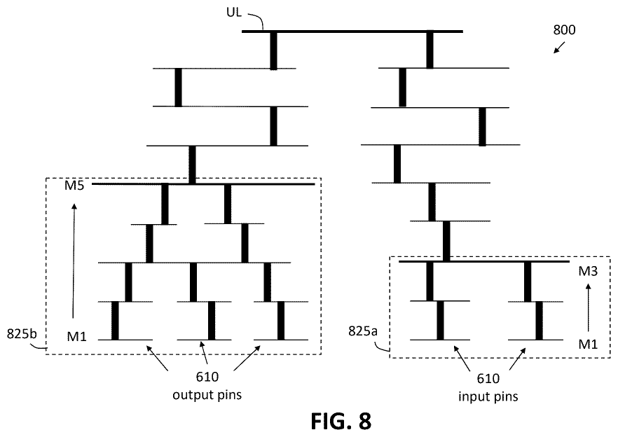

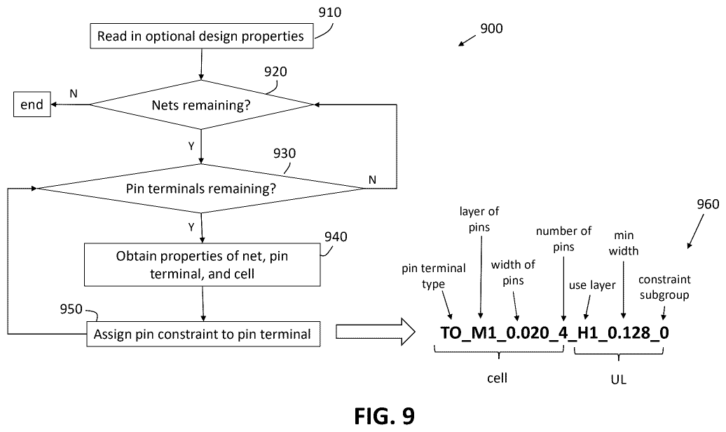

At block 740, defining a via mesh specification 650 includes obtaining a resistance estimation for each via mesh specification 650 that is generated. The maximum strength via mesh 600 can be created for each group of cells, and lower strength options for the via mesh 600 can then be derived. At block 750, verifying routability results in only universally routable (i.e., routable regardless of placement) via mesh specifications 650 being retained in the library. Routability refers to the cell being interconnectable to other cells through a net while meeting all design rules. Generally, individual placement and packed placement scenarios are considered for each cell, as further discussed with reference to FIGS. 8 and 9. Any via mesh 600 that is deemed not to be universally routable is eliminated from the via mesh specification library entries for the group of cells.

As FIG. 7 indicates, defining via mesh specifications (at block 740) and verifying routability (at block 750) are performed iteratively until all via mesh options for all cells of a group are considered. The routability determination does not require actual layout of a given via mesh 600. Thus, a large number of via mesh options with a variety of strengths and heights can be tested for routability according to one or more embodiments of the invention. Only via mesh specifications 650 that are routable regardless of placement are retained in the library (at block 760).

FIG. 8 shows an exemplary net 800 that forms a logical connection between the input pins 610 of one cell 825a and the output pins 610 of another cell 825b according to exemplary embodiments of the invention. The cells 825a, 825b are referred to collectively as cells 825. The exemplary cells 825a and 825b are both shown with representations of via mesh specifications 650. However, only one of the cells 825 can have a via mesh 600 according to alternate embodiments of the invention. A wire code (WC) indicates constraints that are placed on the net 800. The WC can indicate minimum wire width and spacing, for example. The width is based on timing criticality, with more critical nets having a higher minimum wire width. The use layer (UL) is a constraint on the net 800 that indicates the longest wire and the one that interconnects the two portions of the net 800 that each connect to one of the cells 825a, 825b, as indicated. The UL can be a range of layers 605 or a single layer 605, as shown in the exemplary case. The UL is generally at a higher layer 605 based on increased timing criticality of a net 800.

As FIG. 8 illustrates, connecting input pins 610 of one cell 825a with output pins 610 of another cell 825b requires not only the net 800 but also the via mesh 600 of one or both of the cells 825. The via mesh 600 for a cell 825 is selected from among the available universally routable via mesh specifications 650 that are generated according to one or more embodiments of the invention and stored in the library for the group to which the cell 825 belongs. The selected via mesh 600 must be suited to the net 800 in consideration of both timing and routing congestion. As further discussed with reference to FIGS. 8 and 9, the pin terminal constraints, referred to as pin constraints 960 (FIG. 9) and created to indicate net specifications, can be modified to also indicate the via mesh specification 650 to be selected from the library according to one or more embodiments of the invention. That is, each pin constraint 960 includes information pertaining to a corresponding via mesh specification 650. That corresponding via mesh specification 650 may or may not be among the universally routable via mesh specifications 650 in the library that is populated at block 960, as further discussed with reference to FIG. 9.

FIG. 9 is a process flow of a methodology 900 of assigning pin constraints 960 that facilitates selection from among universally routable via mesh specifications 650 according to one or more embodiments of the invention. Once the structure of the net 800 is defined, the processes shown in FIG. 9 can be performed at any time. At block 910, reading in optional design properties refers to design properties that can limit the strength of the via mesh 600 that can be used. At block 920, a check is done of whether nets 800 that interconnect cells 825 remain without already having been processed to assign pin constraints 960. If not, then the process flow is completed, as indicated. If the check at block 920 indicates that there is at least one net 800 that has not yet been processed, the check at block 930 is performed. At block 930, it is determined if pin terminals (i.e., one or a set of pins 610) remain without an assignment of a pin constraint 960. If not, then the check at block 920 is repeated. If there is at least one pin terminal without an assignment of a pin constraint 960, then the processes at block 940 are performed.

At block 940, the processes include obtaining properties of the net 800, the pin terminal, and the cell 825. Assigning a pin constraint 960 to the pin terminal, at block 950, refers to selecting from an existing look up table of pin constraints 960. The table of pin constraint 960 is predefined along with a corresponding table of resistance and capacitance (RC) entries.

An exemplary pin constraint 960 is shown. As indicated, the pin constraint 960 is modified from prior pin constraint naming conventions such that cell properties are encoded in the name along with net 800 and, more specifically, UL properties. The properties of the cell 825 that are part of the pin constraint 960 include the pin terminal type (i.e., input or output), the layer of the pins 610 (e.g., the first metal layer, M1), the width of the pins 610 (e.g., in micrometers (microns)), and the number of pins 610 (i.e., the number of must-connect pins). The properties of the UL that are part of the pin constraint 960 include the layer 605 identification, the minimum width according to the wire code at the UL, and the constraint subgroup property (e.g., 0, 1, 2) according to the wire code, which indicates the strength of the via mesh 600 for the cell 825.

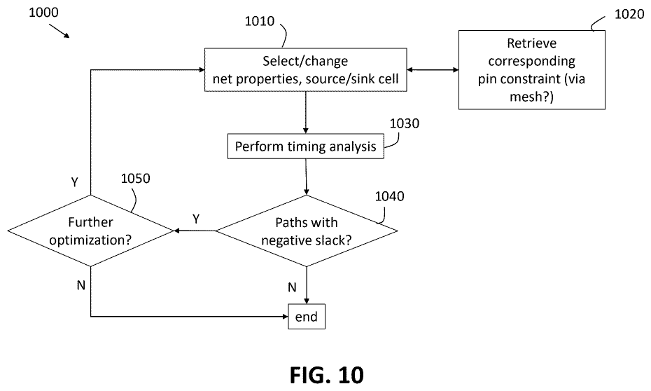

As previously noted, the processes shown in FIG. 9 can be performed at any time. The pin constraint 960 that is assigned at block 950 may or may not correspond with a via mesh specification 650 that is part of the library of universally routable versions of the via mesh 600. For example, it could occur that none of the via meshes 600 are compatible with a width of the pins 610 that is 0.020 microns. FIG. 10 describes the processes involved in optimizing the IC design 212. When the pin constraint 960 corresponding with a selected net 800 has a corresponding universally routable via mesh 600 based on the library entries, then the optimization process benefits from improved accuracy in timing analysis, as discussed.

FIG. 10 is a process flow of a methodology 1000 of selecting a universally routable version of the via mesh 600 as part of an optimization process according to one or more embodiments of the invention. The optimization process refers to the process of adjusting the IC design 212 iteratively to ensure that timing requirements are met. At block 1010, the processes include selecting or changing the properties of the net 800 and/or the source or sink cell 825 (i.e., the cell 825 with the input or output terminals). These selections define the properties that make up the pin constraint 960, as indicated in FIG. 9.

At block 1020, retrieving a pin constraint 860 that corresponds with the properties selected at block 1010 includes determining if that pin constraint 960 corresponds with a universally routable via mesh specification 650 from the library. Retrieving the pin constraint 960 is based on matching the specifications defined at block 1010 based on the nomenclature of the pin constraints 960 that is discussed with reference to FIG. 9. This same nomenclature also allows a determination of whether there is a match with a universally routable via mesh specification 650 stored in the library, as also discussed with reference to FIG. 9. If the pin constraint 960 that is retrieved at block 1020 does not have a corresponding universally routable via mesh specification 650, then the pin terminals of the cell 825 are connected to the top layer without the redundancy and corresponding decrease in resistance provided by a via mesh 600. The exemplary embodiments, in which the pin constraint 960 retrieved at block 1020 has a corresponding via mesh specification 650 in the library, are considered. In this case, the timing analysis at block 1030 is improved, as discussed.

At block 1030, performing timing analysis includes considering the via mesh 600, unlike prior optimization processes. This is because, rather than global routes, a specific via mesh 600 and corresponding resistance and capacitance (RC) entry can be used in the timing analysis. A check is done, at block 1040, of whether some paths have negative slack (i.e., timing that does not meet the requirement). If so, then a check is done, at block 1050, of whether another optimization iteration can be added. If so, then the processes beginning at block 1010 are repeated. If the check at block 1040 indicates that none of the paths have negative slack (i.e., all paths meet timing requirements) or if another optimization is not possible according to the check at block 1050, then the processes end.

The approach to via mesh generation and selection according to one or more embodiments of the invention holds several technical effects and technical benefits over prior approaches. As discussed with reference to FIG. 7, the generation considers routability without requiring actual preconstruction of via mesh options that are considered. As a result, any via mesh specification 650 that is obtained from the library for cells 825 within a given group is guaranteed to be routable regardless of the placement of the cell 825. In addition, the modification of the pin constraint 960 facilitates selection (when available) of a particular via mesh specification 650 from the library in accordance with the assigned pin constraint 960. This ensures that the via mesh 600 and the net 800 meet all design requirements. Still further, the optimization process that results in the final assignment of the pin constraints takes into account the timing of the via mesh 600 and thereby provides additional granularity in the analysis.

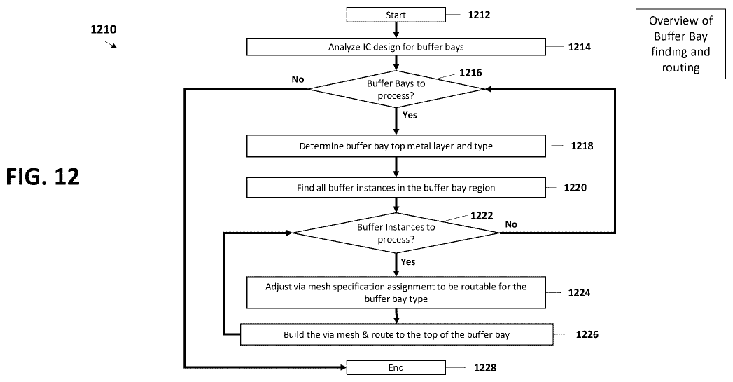

FIG. 11 depicts a computer-implemented methodology 1110 embodying aspects of the invention. In embodiments of the invention, the methodology 1110 can be implemented using the EDA system 210, including specifically the buffer bay identification functionality 240, the via mesh specification updater functionality 242, and the blockage aware buffer bay router functionality 244, to generate the RB-VMF 216 (shown in FIG. 2). In accordance with aspects of the invention, the methodology 1110 includes STEP-01, which identifies buffer bay locations (e.g., buffer bays 350A, 350B, 510) in the IC design 212; STEP-02, which analyzes buffer bay blockages (e.g., 422, 520) to determine the metal layer to escape to (e.g., Metal-5 shown in FIG. 5B); STEP-03, which updates the assigned via mesh specification to be routed for the buffers (e.g., buffers 430) located within the buffer bays (e.g., 350A, 350B, 510); and STEP-04, which execute blockage aware routing operations through blockage aware router functionality 244 for buffer bays (e.g., 350A, 350B, 510). Additional details of how portions of the methodology 1110 can be implemented are illustrated by the methodologies 1210, 1310, 1410, 1510 shown in FIGS. 12, 13, 14, 15, respectively.

FIG. 12 depicts a methodology 1210 that can be implemented using the EDA system 210. The methodology 1210 is a non-limiting example of how aspects of the methodology 1110 can be implemented in accordance with embodiments of the invention, including specifically buffer bay finding and routing operations. In accordance with aspects of the invention, a buffer bay is defined as a region of placement blockage absence in a child design. The methodology 1210 begins at block 1212 then moves to block 1214 to analyze the IC design (e.g., IC design 212) to identify the buffer bays in the IC design. The methodology 1210 moves to decision block 1216 to evaluate whether or not there are additional buffer bays to process. If the answer to the inquiry at decision block 1216 is no, the methodology 1210 moves to block 1228 and ends. If the answer to the inquiry at decision block 1216 is yes, the methodology 1210 moves to block 1218 to determine the buffer bay top metal layer and type associated with the buffer bay. For example, in the horizontal buffer bays 350A (shown in FIGS. 4A and 4B) the top metal layer is Metal-4. In the vertical buffer bay 350B (shown in FIGS. 4A and 4B), the top metal layer is Metal-1. The methodology 1210 moves to block 1220 and finds the location of the buffers (e.g., buffers 430 shown in FIGS. 4A and 4B) in the buffer bay under evaluation.

The methodology 1210 moves to decision block 1222 to evaluate whether there are any additional buffer instances in the buffer bay to process. If the answer to the inquiry at decision block 1222 is no, the methodology 1210 returns to decision block 1216 to evaluate whether or not there are additional buffer bays in the IC design 212 to process. If the answer to the inquiry at decision block 1222 is yes, the methodology 1210 moves to block 1224 to adjust the relevant via-mesh specification assignment to be routable for the buffer bay type. The methodology 1210 moves to block 1226 to build the via-mesh (i.e., RB-VMF 216 shown in FIG. 2). The methodology 1210 returns to decision block 1222 to determine whether or not there are additional instances of buffers in the buffer bay to process.

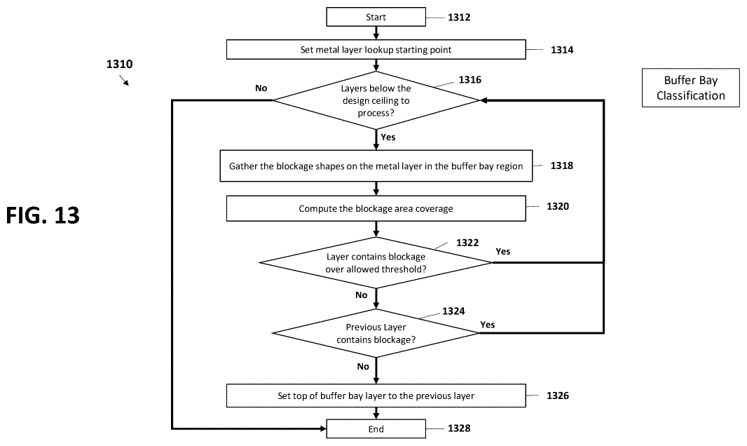

FIG. 13 depicts a methodology 1310 that can be implemented using the EDA system 210. The methodology 1310 is a non-limiting example of how the buffer bay classification operations can be performed in accordance with embodiments of the invention. Using the methodology 1310, the starting layer for the blockage processing input parameters are determined by design requirements. For example, buffer bay designs can start their blockages at different layers (i.e., M4 instead of M1), based upon design requirements, as such the parameter should be set approximately where the first blockage layer of the buffer bay exists. The layer blockage threshold is a tunable parameter based on technology and design requirements. For example, a 50 percent blockage coverage could be used. As mentioned previously, there exists two types of buffer bays, horizontal and vertical, by which their available resource is defined. Horizontal buffer bays are vertically limited in the resource that is available and will have a top of buffer bay that is on a vertical layer (because the next vertical layer is not blocked) and horizontal buffer bays will have a vertical top of buffer bay (because the next horizontal layer is not blocked). Thus, the buffer bay type is defined from the direction to the preferred routing direction of the top of buffer bay layer. In other words, if the top of buffer bay layer has a vertical routing direction, the buffer bay is classified as a vertical buffer bay.

The methodology 1310 begins at block 1312 then moves to block 1314 to set a starting point for performing metal layer lookup operations. The methodology 1310 moves to decision block 1316 to evaluate whether or not there are metal layers below the design ceiling to process. If the answer to the inquiry at decision block 1316 is no, the methodology 1310 moves to block 1328 and ends. If the answer to the inquiry at decision block 1316 is yes, the methodology 1310 moves to block 1318 to gather blockage shapes on the metal layer in the buffer bay region. The methodology 1310 moves to block 1320 and computes the coverage of the blockage area.

The methodology 1310 moves to decision block 1322 to evaluate whether the layer contains blockage over the allowed threshold. If the answer to the inquiry at decision block 1322 is yes, the methodology 1310 moves to decision block 1316 to again evaluate whether or not there are layers below the design ceiling to process. If the answer to the inquiry at decision block 1322 is no, the methodology moves to decision block 1324. If the answer to the inquiry at decision block 1324 is yes, the methodology 1310 moves to decision block 1316 to again evaluate whether or not there are layers below the design ceiling to process. If the answer to the inquiry at decision block 1324 is no, the methodology 1310 moves to block 1326 to set the top of the buffer bay layer to the previous layer. These steps (at block 1322 and block 1324) are gathering the blockage shapes over the buffer bay to determine the amount of free routable area. This value is compared to the threshold value to determine if the layer is blocked. The threshold value is in place as there may still be parent blockage in place for other design needs, so it may not be completely unblocked if the child is not blocking the region. The methodology 1310 then moves to block 1328 and ends.

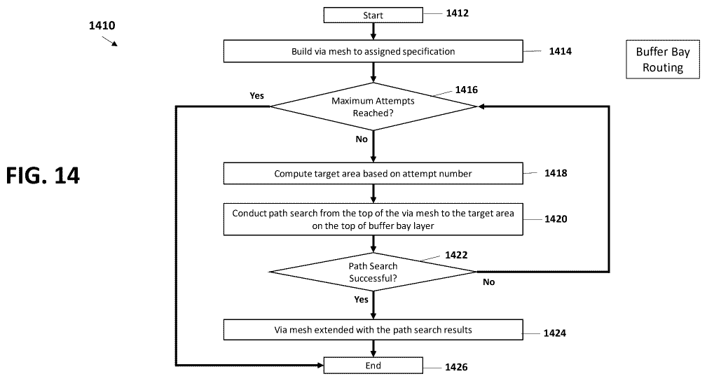

FIG. 14 depicts a methodology 1410 that can be implemented using the EDA system 210. The methodology 1410 is a non-limiting example of how buffer bay routing (e.g., the RB-VMF 216 shown in FIG. 2) can be generated in accordance with embodiments of the invention. Using methodology 1410, the maximum attempts are tunable to balance runtime vs success; the target area expands as the attempt number increases; and the base area and expansion rate are tunable based on technology and design requirements. With a large search area the computation to determine a path increases, but more flexibility is provided to the router to find a solution that needs to navigate further. Thus, the path search area should only be expanded if the path search is not successful, to provide the router (e.g., the blockage aware buffer bay router functionality 244) with additional flexibility.

The methodology 1410 begins at block 1412 then moves to block 1414 to build the via-mesh to assigned specification in the manner previously described herein (e.g., FIGS. 6A, 6B, 7). The methodology 1410 moves to decision block 1416 to evaluate whether or not the maximum attempts have been reached. “Maximum attempts” refer to attempts to route the connection “flue” from the via mesh to the top of the buffer bay. If the answer to the inquiry at decision block 1416 is yes, the methodology 1410 moves to block 1428 and ends. If the answer to the inquiry at decision block 1416 is yes, the methodology 1410 moves to block 1418 to compute the target area based on the attempt number. The target area is computed by a set of expansion factors based upon the current attempt number. As the attempt number increases, so do the expansion factors and thus the area. Increasing the target area provides the router with more flexibility to find a successful path, but at the cost of runtime in construction and execution of the path search. The methodology 1410 moves to block 1420 and conducts a path search from the top of the via-mesh to the target area on the top of the buffer bay layer. Because the via mesh that is constructed may or may not be built to the top of the buffer bay layer, the EDA system 210 (shown in FIG. 2) must route the top of the via mesh to the top of the buffer bay (the “flue”).

The methodology 1410 moves to decision block 1422 to evaluate whether or not the path search was successful. If the answer to the inquiry at decision block 1422 is no, the methodology 1410 returns to decision block 1416 to evaluate whether or not the maximum attempts have been reached. If the answer to the inquiry at decision block 1422 is yes, the methodology 1410 moves to block 1424 to extend the via mesh with the path search results. Because the blockages break the routing methodology, to be sure that no future routing calls will disrupt the routing results, the path search results are appended to the via mesh such that the top of the via mesh is extended to the top of the buffer bay. The methodology 1410 then moves to block 1426 and ends.

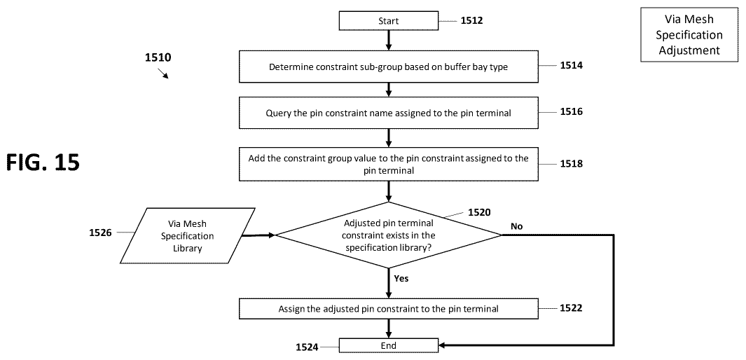

FIG. 15 depicts a methodology 1510 that can be implemented using the EDA system 210. The methodology 1510 is a non-limiting example of how the via mesh specification adjustment can be performed in accordance with embodiments of the invention. Using methodology 1510, the via mesh specification library is extended to incorporate routable via meshes in horizontal and vertical buffer bays. Via meshes are defined for buffer bays such that similar electrical characteristics are maintained to the non-buffer-bay mesh definitions, including mesh resistance and capacitance. Buffer bay meshes are defined with a unique constraint sub group (i.e., 100/200). The mesh specification library and constraint sub group can be defined using known techniques. The unique constraint sub groups provide the ability to define the via mesh specifications into the specification library without being unintentionally assigned. Pin constraints are assigned with “100” sub group for vertical buffer bay mesh specifications. Pin constraints area assigned with “200” sub group for horizontal buffer bay mesh specifications.

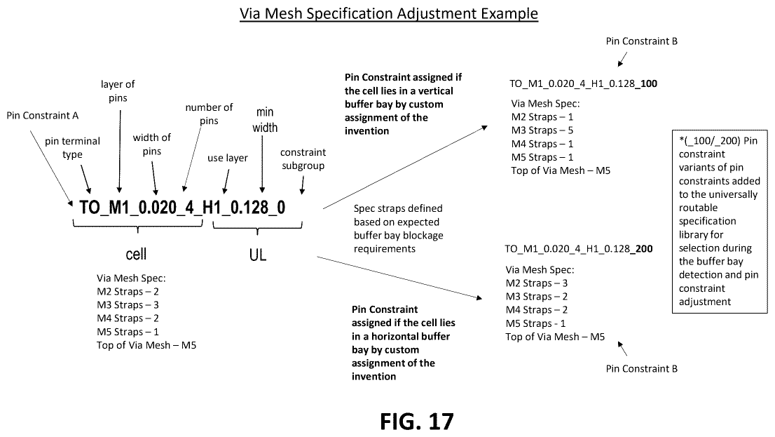

The methodology 1510 begins at block 1512 then moves to block 1514 to determine the constraint sub-group based on buffer bay type. The methodology 1510 moves to block 1516 to query the pin constraint name assigned to the pin terminal. The methodology 1510 move to block 1518 and adds the constraint group value, 100 for vertical buffer bays and 200 for horizontal buffer bays, to the pin constraint assigned to the pin terminal. The methodology 1510 moves to decision block 1520 to access the via mesh specification library from block 1526 and evaluate whether or not the adjusted pin terminal constraint exists in the specification library, by process shown in FIG. 17. If the answer to the inquiry at decision block 1520 is no, the methodology 1510 moves to block 1524 and ends. If the answer to the inquiry at decision block 1516 is yes, the methodology 1510 moves to block 1522 to assign the adjusted constraint to the pin terminal. The methodology then moves to block 1524 and ends. Additional explanations of the concepts depicted in FIG. 15 are depicted in FIG. 17 and explained in greater detail subsequently herein.

The methodology 1510 moves to decision block 1522 to evaluate whether there are any additional buffer instances in the buffer bay to process. If the answer to the inquiry at decision block 1522 is no, the methodology 1510 returns to decision block 1516 to evaluate whether or not there are additional buffer bays in the IC design 212 to process. If the answer to the inquiry at decision block 1522 is yes, the methodology 1510 moves to block 1524 to adjust the via-mesh specification assignment to be routable for the buffer bay type or category. The methodology 1510 moves to block 1526 to build the via-mesh using the techniques described herein. The methodology 1510 returns to decision block 1522 to determine whether or not there are additional instances of buffers in the buffer bay to process.

FIG. 16 depicts a simplified block diagram illustrating an example routing connection between one or more output pins of a buffer within a buffer bay and a cell placed outside of the buffer bay. A buffer bay via mesh is routed for the output pins located within the buffer bay which is then extended to the top of the buffer bay by the Flue. This flue extension provides the router with an access point by which it can connect to without needing to traverse the buffer bay blockage patterns. The non buffer bay via mesh is routed for the cell outside of the buffer bay for the input terminal. The bulk routing connection is then made to connect the extended top of the via mesh at the buffer bay top layer as well as the top of the input via mesh.

FIG. 17 illustrates a non-limiting example of a via mesh specification adjustment operation performed in accordance with embodiments of the invention. Pin constraint A represents an example pin constraint which corresponds to a via mesh specification that exists in the (universally routable) via mesh specification library 252. This via mesh specification is determined to not be routable in buffer bays due to the allocation of routing resource. Thus, new variants of this pin constraint are created, pin constraint B and pin constraint C, and these constraints are differentiated by their constraint sub-group numbering. The constraint sub group value of 100 is used to identify that the pin constraint is assignable in vertical buffer bays, while a value of 200 is used to identify the pin constraint is assignable in horizontal buffer bays. These pin constraints alter corresponding via mesh specifications such that the via mesh is routable in their corresponding buffer bays and the RC characteristics are similar to the original pin constraint via mesh.

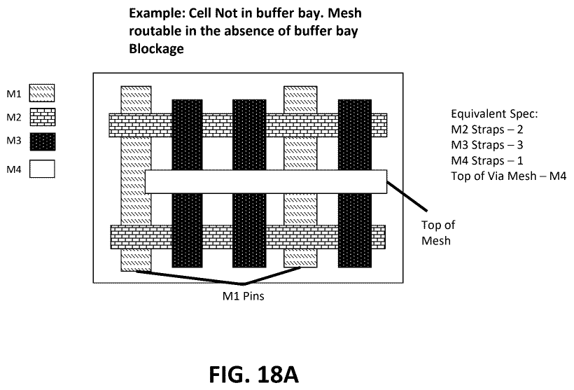

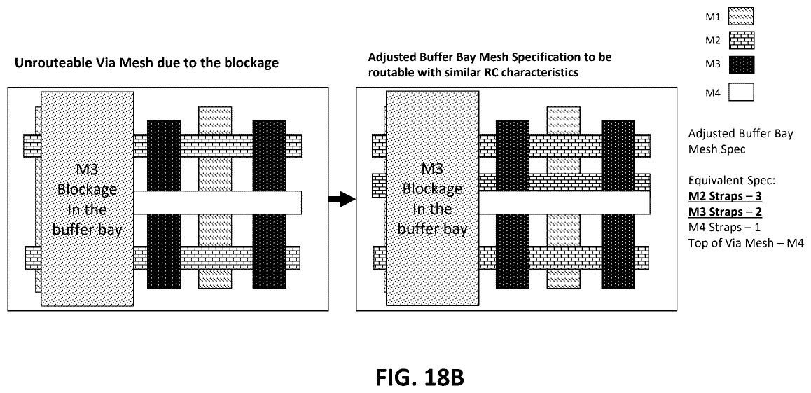

FIG. 18A illustrates a non-limiting example of a cell that has a non-buffer bay mesh routed. An example mesh is routed for a buffer with a via mesh specification from the (universally routable) via mesh specification library 252 and assigned through prior embodiments. This mesh is built to M4 with a strap distribution of two (2) M2 and three (3) M3 straps connecting to M1 terminal pins of the cell.

FIG. 18B illustrates a non-limiting example of a cell in an unrouteable via mesh due to the blockage, along with an adjusted buffer bay via mesh specification configured to be routable with similar RC characteristics. In this non-limiting example, the via mesh from FIG. 18A is unrouteable due to the buffer bay blockage which exists on M3. In correspondence with this, the via mesh specification needs to be updated to re-allocate the via mesh straps on other layers to maintain the RC characteristics. In this example the via mesh specification is adjusted to remove an M3 strap and add an M2 strap to recover the RC loss that results from losing the M3 strap, resulting in a via mesh specification that is both routable and maintains similar RC characteristics.

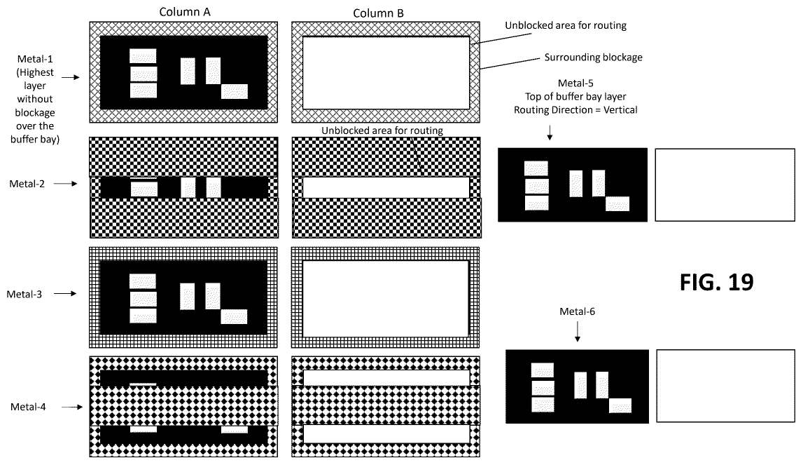

FIG. 19 depicts a simplified block diagram of vertical buffer bays and associated blockage patterns to which embodiments of the invention can be applied. For each metal layer of the depicted buffer bays this illustration depicts the resource allocation from the child to the parent. Column A depicts the blockage pattern of the associated layer, while also showing example buffer elements to give context of the route path that would be needed to connect the buffer through the blockage. Column B shows the blocked area of the buffer bay, along with the resource that's available to the parent to be used to establish connections to the buffers that are placed in the buffer bay. Looking at horizontal layer Metal-1, this represents the top most layer of the buffer bay that is fully available to the parent, besides the surrounding blockage which requires the connection to be made from the layer above. Metal-2 represents a horizontal layer which has resource allocated to the child as denoted by the blockage, while maintaining the surrounding blockage. This pattern of vertical layer resource remaining unblocked, besides the surrounding blockage, and horizontal layer resource limited continues until the top of buffer bay layer. At the top of the buffer bay, and the subsequent layer Metal-6, the surrounding blockage is no longer present as it is above the child ceiling. At this layer Metal-5, the buffer bay connection can then be made to net elements which exist outside of the buffer bay.

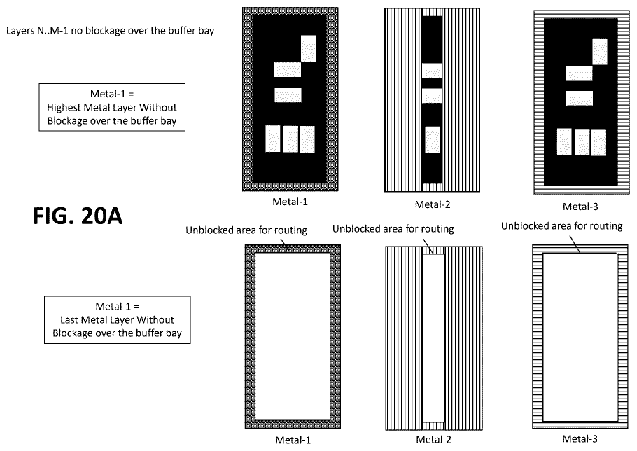

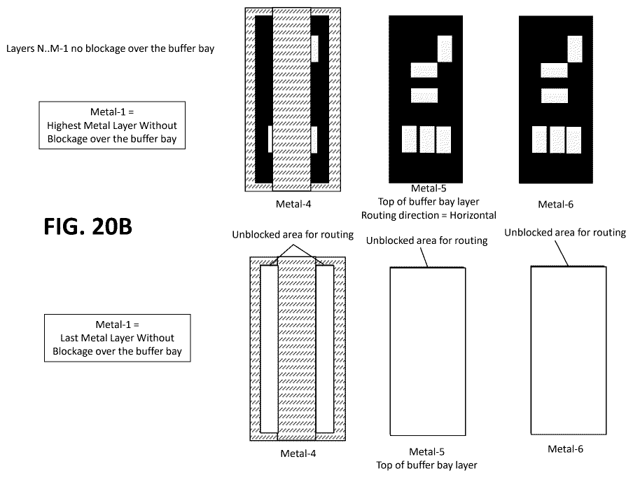

FIG. 20A depicts a simplified block diagram of horizontal buffer bays and associated blockage patterns to which embodiments of the invention can be applied. For each layer of the buffer bay this illustration depicts the resource allocation from the child to the parent. The topmost row of buffer bays depict the blockage pattern of the associated layer, while also showing example buffer elements to give context of the route path that would be needed to connect the buffer through the blockage. The bottommost row of buffer bays shows the blocked area of the buffer bay, along with the resource that's available to the parent to be used to establish connections to the buffers that are placed in the buffer bay. Looking at vertical layer Metal-1, this represents the top most layer of the buffer bay that is fully available to the parent, besides the surrounding blockage which requires the connection to be made from the layer above. Metal-2 represents a vertical layer which has resource allocated to the child as denoted by the blockage, while maintaining the surrounding blockage. Metal-3 represents the next horizontal layer which has no resource allocation to the child, resulting in an unblocked area usable by the parent.

FIG. 20B depicts a simplified block diagram of horizontal buffer bays and associated blockage patterns to which embodiments of the invention can be applied. This pattern from FIG. 20A of horizontal layer resource remaining unblocked, besides the surrounding blockage, and vertical layer resource limited continues until the top of buffer bay layer. At the top of the buffer bay, and the subsequent layer Metal-6, the surrounding blockage is no longer present as it is above the child ceiling. At this layer Metal-5, the buffer bay connection can then be made to net elements which exist outside of the buffer bay.

Thus it can be seen from the foregoing detailed description that embodiments of the invention provide technical effects and technical benefits. For example, embodiments of the invention provides systems and computer-implemented methods of identifying buffer bays and the buffers placed within then, switching the assigned via mesh specification to one which is routable through the buffer bay blockage, finding a routing path through the buffer bay blockage and extending the via mesh with a flue to the top of the buffer bay. This allows for seamless integration of buffer bays into the bulk routing methodology, requiring no further adaptation of the tools to handle buffer bays.

This detailed description illustrates the general principles of the invention and is not meant to limit the inventive concepts claimed herein. In this detailed description, numerous details are set forth in order to provide an understanding of ICs, VLSI chips, via mesh interconnect configurations, and blockage aware flue routing operations for buffer bays. However, it will be understood by those skilled in the art that different and numerous embodiments of the IC, VLSI chip, VLSI chip module/package, architectural structure, system, and method of fabrication can be practiced without those specific details, and the claims and invention should not be limited to the embodiments, subassemblies, systems, structures, features, processes, methods, aspects, and/or details specifically described and shown herein. Further, particular features described herein can be used in combination with other described features in various possible combinations and permutations.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc.

The terms “a plurality” are understood to include any integer number greater than or equal to two, i.e. two, three, four, five, etc. The term “connection” can include both an indirect “connection” and a direct “connection.” The terms “about,” “substantially,” “approximately,” and variations thereof, are intended to include the degree of error associated with measurement of the particular quantity based upon the equipment available at the time of filing the application. For example, “about”can include a range of ±8% or 5%, or 2% of a given value.

As used herein, in the context of machine learning algorithms, the terms “input data,” and variations thereof are intended to cover any type of data or other information that is received at and used by the machine learning algorithm to perform training, learning, and/or classification operations.

As used herein, in the context of machine learning algorithms, the terms “training data,” and variations thereof are intended to cover any type of data or other information that is received at and used by the machine learning algorithm to perform training and/or learning operations.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

It will be understood that those skilled in the art, both now and in the future, may make various improvements and enhancements which fall within the scope of the claims which follow.

What is claimed is:

1. A computer-implemented method of performing routing operations for an integrated circuit (IC) design, the computer-implemented method comprising:
identifying, using a processor system, a location of a buffer bay in the IC design;
identifying, using the processor system, one or more blockage areas associated with the buffer bay;
determining, using the processor system, a pattern of the one or more blockage areas, wherein the pattern defines one or more blockage area exit locations;
placing a component within the buffer bay; and
based at least in part on information of the pattern, determining a routing path from the component through the pattern to one of the one or more blockage area exit locations.

2. The computer-implemented method of claim 1, wherein:
the buffer bay comprises one or more buffer bay regions;
the one or more buffer bay regions comprise unblocked areas where placement and routing can occur; and
placing the component within the buffer bay comprises placing the component in one of the one or more buffer bay regions.

3. The computer-implemented method of claim 2, wherein determining the routing path from the component through the pattern of the one or more blockage areas to the blockage area exit locations is further based at least in part on information of a pattern of the one or more buffer bay regions.

4. The computer-implemented method of claim 3, wherein determining the routing path from the component through the pattern of the one or more blockage areas to the blockage area exit locations is further based at least in part on an orientation of the buffer bay.

5. The computer-implemented method of claim 4, wherein the orientation of the buffer bay comprises a horizontal orientation.

6. The computer-implemented method of claim 4, wherein the orientation of the buffer bay comprises a vertical orientation.

7. The computer-implemented method of claim 1 further comprising extending the routing path from the blockage area exit locations through a flue region of the IC design to a set of interconnects comprising a universally routable via mesh configuration.

8. A computer system for performing routing operations for an integrated circuit (IC) design, the computer system comprising a processor system electronically coupled to a memory, wherein the processor system is configured to perform processor system operations comprising:
identifying a location of a buffer bay in the IC design;
identifying one or more blockage areas associated with the buffer bay;
determining a pattern of the one or more blockage areas, wherein the pattern defines one or more blockage area exit locations;
placing a component within the buffer bay; and
based at least in part on information of the pattern, determining a routing path from the component through the pattern to one of the one or more blockage area exit locations.

9. The computer system of claim 8, wherein:
the buffer bay comprises one or more buffer bay regions;
the one or more buffer bay regions comprise unblocked areas where placement and routing can occur; and
placing the component within the buffer bay comprises placing the component in one of the one or more buffer bay regions.

10. The computer system of claim 9, wherein determining the routing path from the component through the pattern of the one or more blockage areas to the blockage area exit locations is further based at least in part on information of a pattern of the one or more buffer bay regions.

11. The computer system of claim 10, wherein determining the routing path from the component through the pattern of the one or more blockage areas to the blockage area exit locations is further based at least in part on an orientation of the buffer bay.

12. The computer system of claim 11, wherein the orientation of the buffer bay comprises a horizontal orientation.

13. The computer system of claim 11, wherein the orientation of the buffer bay comprises a vertical orientation.

14. The computer system of claim 8 further comprising extending the routing path from the blockage area exit locations through a flue region of the IC design to a set of interconnects comprising a universally routable via mesh configuration.

15. A computer program product for performing routing operations for an integrated circuit (IC) design, the computer program product comprising a computer readable program stored on a computer readable storage medium, wherein the computer readable program, when executed on a processor system, causes the processor system to perform processor system operations comprising:
identifying a location of a buffer bay in the IC design;
identifying one or more blockage areas associated with the buffer bay;
determining a pattern of the one or more blockage areas, wherein the pattern defines one or more blockage area exit locations;
placing a component within the buffer bay; and
based at least in part on information of the pattern, determining a routing path from the component through the pattern to one of the one or more blockage area exit locations.

16. The computer program product of claim 15, wherein:
the buffer bay comprises one or more buffer bay regions;
the one or more buffer bay regions comprise unblocked areas where placement and routing can occur; and
placing the component within the buffer bay comprises placing the component in one of the one or more buffer bay regions.

17. The computer program product of claim 16, wherein determining the routing path from the component through the pattern of the one or more blockage areas to the blockage area exit locations is further based at least in part on information of a pattern of the one or more buffer bay regions.

18. The computer program product of claim 17, wherein determining the routing path from the component through the pattern of the one or more blockage areas to the blockage area exit locations is further based at least in part on an orientation of the buffer bay.

19. The computer program product of claim 18, wherein the orientation of the buffer bay is selected from the group consisting of a horizontal orientation and a vertical orientation.

20. The computer program product of claim 15 further comprising extending the routing path from the blockage area exit locations through a flue region of the IC design to a set of interconnects comprising a universally routable via mesh configuration.
